(19) United States
(12) Patent Application Publication
(10) Pub. No.: US 2013/0109186 A1
(43) Pub. Date: May 2, 2013

(54) METHOD OF FORMING SEMICONDUCTOR DEVICES USING SMT

(71) Applicants: Wenguang ZHANG, Shanghai (CN); Qiang XU, Shanghai (CN); Chunsheng Zheng, Shanghai (CN); Lingzhi Xu, Shanghai (CN); Yuwen Chen, Shanghai (CN)

(72) Inventors: Wenguang ZHANG, Shanghai (CN); Qiang XU, Shanghai (CN); Chunsheng Zheng, Shanghai (CN); Lingzhi Xu, Shanghai (CN); Yuwen Chen, Shanghai (CN)

(73) Assignee: Shanghai Huali Microelectronics Corporation

(21) Appl. No.: 13/662,277

(22) Filed: Oct. 26, 2012

(30) Foreign Application Priority Data
Nov. 2, 2011 (CN) 201110341094.5

(51) Int. Cl. H01L 21/302

(52) U.S. Cl. 438/703; 257/E21.214

(57) ABSTRACT

The present invention provides a method of forming semiconductor devices using SMT. The method comprises providing a substrate; depositing an SiO₂ buffer film and a low tensile stress SiN film on the substrate; applying photoresist over the low tensile stress SiN film and exposing the low tensile stress SiN film on the NMOS region through photoresist exposure; applying UV radiation to the exposed low tensile stress SiN film; removing some hydrogen in the low tensile stress SiN film on the NMOS region and removing photoresist over the PMOS region; performing a rapid thermal annealing process to induce tensile stress in the NMOS channel region; and removing the SiN film and the SiO₂ buffer film. According to the method of forming semiconductor devices using SMT of the present invention, the conventional SMT is greatly simplified.

### CROSS-REFERENCE TO RELATED APPLICATION

This application claims the priority benefit of China application serial no. 201110341094.5, filed Nov. 2, 2011. All disclosure of the China application is incorporated herein by reference.

### FIELD OF THE INVENTION

The present invention relates to a Stress Memorization Technique (SMT) application method, and more particularly to an SMT application method for simplifying SMT and reducing costs.

### BACKGROUND OF THE INVENTION

With the wide use of electronic devices, semiconductor manufacturing technology has developed rapidly. Since the feature size of integrated circuit has been reduced to below 90 nanometers, high stress SiN technology is introduced to increase carrier mobility. Being adopted widely in semiconductor manufacturing, SMT can induce stress into MOSFET channel region after ion implantation process in the source/drain region, so as to change the semiconductor component characteristics.

The method to implement SMT includes depositing a high tensile stress SiN (SiN) layer and carrying out an Rapid Thermal Annealing (RTA) operation to make the stress in the SiN layer “memorized” in the NMOS channel region, and the tensile stress allows for increased mobility of the NMOS electrons through the channel region. Specifically, the method using SMT in semiconductor components includes the following steps: Providing a semiconductor substrate including PMOS region (the region where a PMOS transistor is formed), NMOS region (the region where an NMOS transistor is formed), P-well, N-well, and a shallow trench isolation (STI) region isolating the PMOS region from the NMOS region; forming the MOS gate and gate sidewall spacers on lateral surfaces of the MOS gate; forming source/drain region through ion implantation; depositing a high stress SiN layer and recrystallizing the MOS gate to improve the electrical performance of the components; removing the SiN layer by dry etching or plasma etching.

Generally, the chemical substance used in dry etching includes inert gas such as fluoromethane, oxygen, helium, argon, etc. For example, a high tensile stress SiN layer having a thickness of 500 Å can be removed by dry etching using mixed inert gas of 200 sccm fluoromethane, 125 sccm oxygen and 200 sccm helium under a vacuum pressure of 40 mTorr and a biased voltage of 400V. The main etching requires 46.9 seconds and the over etching requires 60 seconds.

However, since the high tensile stress SiN film may resist the carriers mobility through the PMOS channel region, the SiN film deposited on the PMOS region need to be removed, which requires process of photoetching, etching and cleaning. Therefore, process cost of SMT is increased.

### SUMMARY OF THE INVENTION

Accordingly, at least one objective of the present invention is to provide a method of forming semiconductor devices using SMT to simplify the conventional SMT process sequentially and increase the integrity of the SiN film. This reduces the process cost of SMT and ensures the performance of the NMOS transistor without affecting the performance of the PMOS transistor.

To achieve these and other advantages and in accordance with the objective of the invention, as embodied and broadly described herein, the invention provides a method of forming semiconductor devices using SMT. The method includes the following steps:

Step 1: providing a substrate including NMOS region and PMOS region;

Step 2:depositing an SiO₂ buffer film and a low tensile stress SiN film on the substrate followed by applying photoresist over the low tensile stress SiN film;

Step 3: exposing the low tensile stress SiN film on the NMOS region through photoresist exposure and applying UV radiation to the exposed low tensile stress SiN film; removing some hydrogen element in the low tensile stress SiN film on the NMOS region and removing photoresist over the PMOS region;

Step 4: performing a rapid thermal annealing process to induce high tensile stress in the NMOS channel region;

Step 5: removing the SiN film and the SiO₂ buffer film. In one embodiment of the present invention, the SiO₂ buffer film is deposited by PECVD or SACVD.

In one embodiment of the present invention, the SiO₂ buffer film has a thickness of about 50 Å˜200 Å.

In one embodiment of the present invention, the stress of the low tensile stress SiN film has a magnitude in the range from about 200 MPa to 400 MPa.

In one embodiment of the present invention, the low tensile stress SiN film has a thickness of about 200 Å˜800 Å.

In one embodiment of the present invention, the stress of the low tensile stress SiN film has a magnitude in the range from about 1000 MPa to 1800 MPa after being exposed and applied UV radiation in step 3.

In one embodiment of the present invention, the UV radiation is applied for about 1 minute to 10 minutes.

According to the method of forming semiconductor devices using SMT of the present invention, the conventional SMT is greatly simplified and the integrity of the SiN film is improved. Therefore, the method of the present invention can reduce the process cost of SMT and ensure the performance of the NMOS transistor without affecting the performance of the PMOS transistor.

### BRIEF DESCRIPTION OF THE DRAWINGS

The method of forming semiconductor devices using SMT of the present invention will be elucidated by reference to the following embodiments and the accompanying drawings, in which:

FIG. 1 is a cross-sectional view of a substrate in one embodiment of the present invention;

FIG. 2 is a cross-sectional view of the substrate after depositing an SiO₂ buffer film and a low tensile stress SiN film and applying photoresist in one embodiment of the present invention;

FIG. 3 is a cross-sectional view of the substrate after exposing the low tensile stress SiN film on the NMOS region in one embodiment of the present invention;

FIG. 4 is a cross-sectional view of the substrate after applying UV radiation in one embodiment of the present invention;

FIG. 5 is cross-sectional view of the substrate after photoresist over the PMOS region in one embodiment of the present invention;

FIG. 6 is cross-sectional view of the substrate during the rapid thermal annealing process in one embodiment of the present invention; and

FIG. 7 is a curve of stress magnitude of SiN film and hydrogen element content with time in one embodiment of the present invention.

### DETAILED DESCRIPTION OF THE EMBODIMENTS

The method of forming semiconductor devices using SMT of the present invention will be described in further details hereinafter with respect to three embodiments and the accompanying drawings.

According to the present invention, the conventional SMT process is simplified

### First Embodiment

Step 1: providing a substrate.

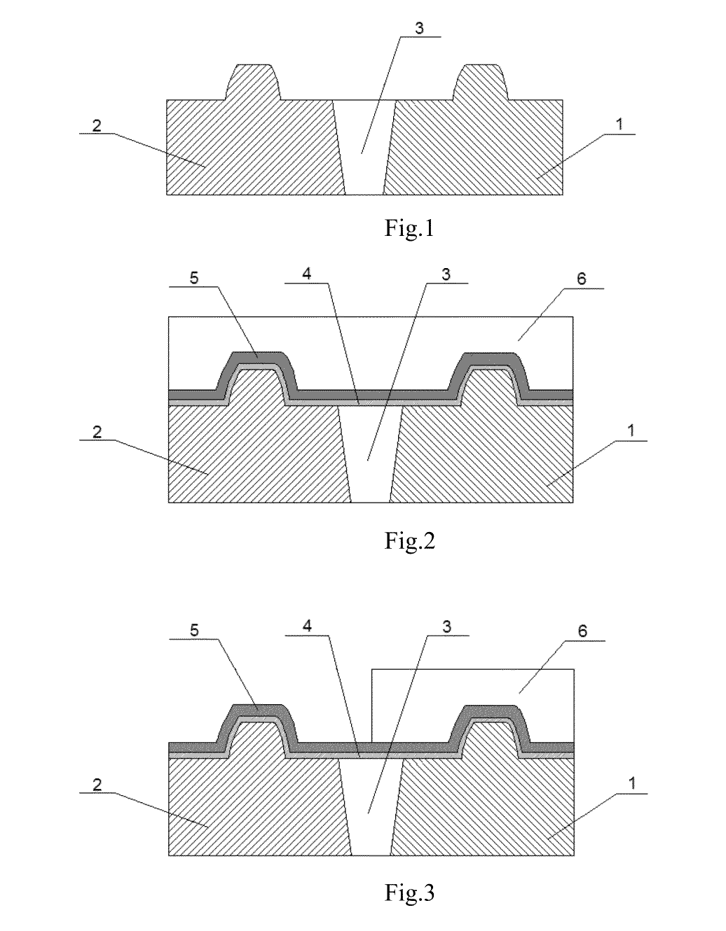

Referring to FIG. 1 of the drawings, the substrate includes PMOS region 1 (the region where an NMOS transistor is formed), NMOS region 2 (the region where an NMOS transistor is formed), and a shallow trench isolation (STI) region 3 isolating the PMOS region 1 from the NMOS region 2. A PMOS gate electrode and an NMOS gate electrode are formed on the PMOS region 1 and the NMOS region 2 respectively. P-type source/drain regions are formed adjacent to the PMOS gate electrode and N-type source/drain regions are formed adjacent to the NMOS gate electrode.

Step 2: deposition.

Referring to FIG. 2 of the drawings, an silicon oxide (SiO₂) buffer film 4 having a thickness of about 50 Å is deposited on the substrate via Plasma Enhanced Chemical Vapor Deposition (PECVD) or Sub-atmospheric Chemical Vapor Deposition (SACVD), the gate electrode, the source/drain regions of the PMOS region 1 and the NMOS region 2 as well as the STI region 3 are all covered by the SiO₂ buffer film 4. Then, a low tensile stress SiN film 5 having a thickness of about 200 Å and stress magnitude of about 200 MPa is deposited on the SiO₂ buffer film 4. Afterwards, photoresist 6 is applied over the low tensile stress SiN film 5.

Step 3: UV radiation.

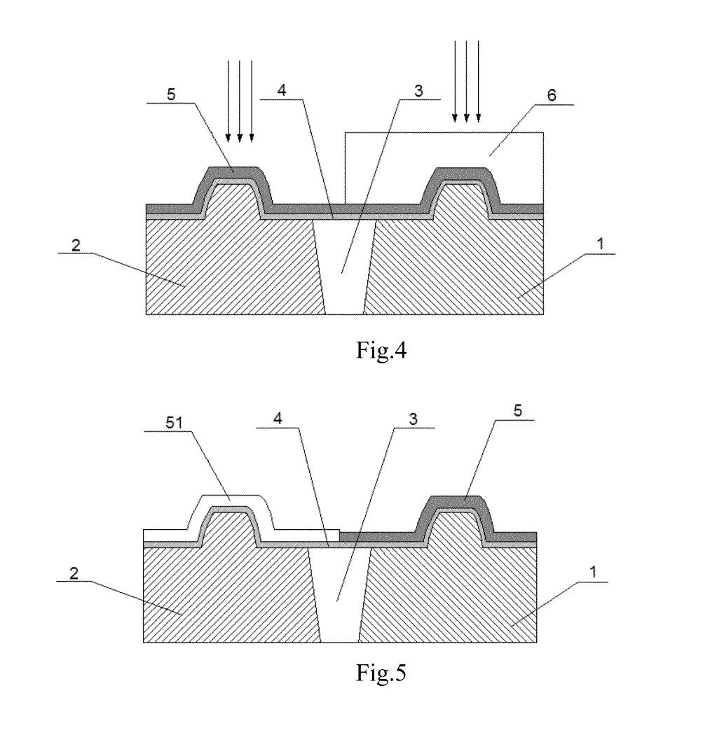

Referring to FIG. 3 of the drawings, the low tensile stress SiN film 5 on the NMOS region 2 is exposed through photoresist exposure. In addition, some SiN film 5 on the STI region 3 can also be exposed.

Referring to FIG. 4 of the drawings, ultraviolet (UV) radiation is applied to the exposed low tensile stress SiN film 5 in a direction illustrated by the arrows in FIG. 4. Since the PMOS region 1 is covered by the photoresist, UV light cannot be radiated on the low tensile stress SiN film 5 on the PMOS region 1. Therefore, the PMOS region 1 will not be affected by UV radiation.

Referring to FIG. 7 of the drawings, the hydrogen element of the low tensile stress SiN film on the NMOS region 2 decreases with the time of UV radiation, while the stress magnitude of the low tensile stress SiN film increases.

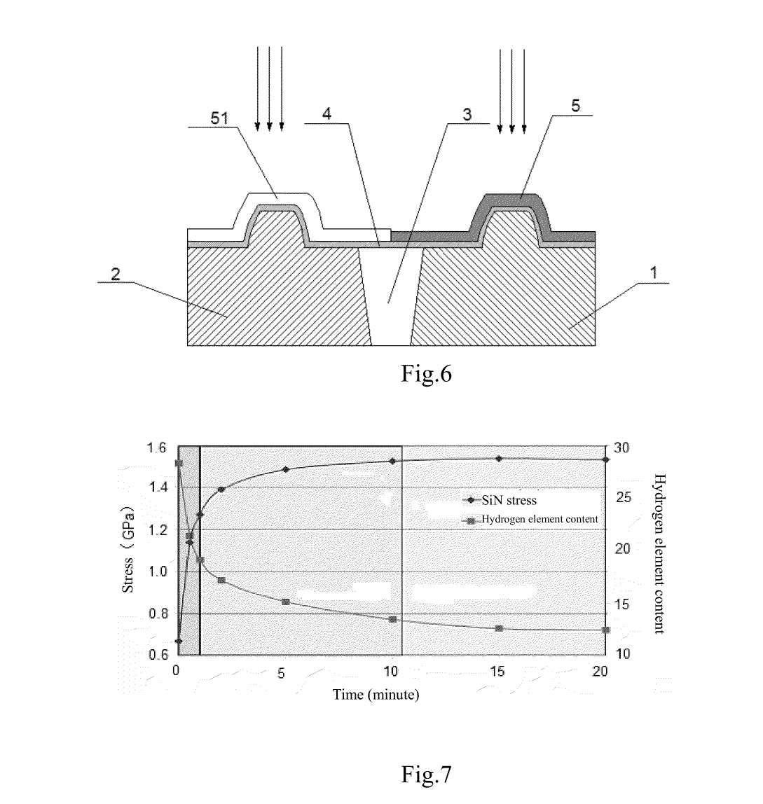

Referring to FIG. 4 and FIG. 5, after UV radiation being applied for 10 minutes, the stress magnitude of the low tensile stress SiN film on NMOS region 2 reaches 1500 MPa. After UV radiation is stopped, a high tensile stress nitride film 51 is formed and the low tensile stress SiN film 5 on PMOS region will not be affected.

Then, the photoresist 6 is removed.

Step 4: Rapid Thermal Annealing (RTA) process.

Referring to FIG. 6, a rapid thermal annealing process is performed and the stress in the high tensile stress nitride film 51 covered on the NMOS transistor is “memorized”, that is, the high tensile stress is induced in the channel region of the NMOS region 2.

Step 5: Removing the SiO₂ buffer film 4, the low tensile stress nitride film 5, and the high tensile stress nitride film 51 on the NMOS region 2.

### Second Embodiment

Step 1: providing a substrate.

Referring to FIG. 1 of the drawings, the substrate includes PMOS region 1, NMOS region 2, and an STI region 3 isolating the PMOS region 1 from the NMOS region 2.

A PMOS gate electrode and an NMOS gate electrode are formed on the PMOS region 1 and the NMOS region 2 respectively. P-type source/drain regions are formed adjacent to the PMOS gate electrode and N-type source/drain regions are formed adjacent to the NMOS gate electrode.

Step 2, deposition.

Referring to FIG. 2 of the drawings, an SiO₂ buffer film 4 having a thickness of about 150 A is deposited on the substrate via PECVD or SACVD, and the gate electrode, the source/drain regions of the PMOS region 1 and the NMOS region 2 as well as the STI region 3 are covered by the SiO₂ buffer film.

Then, a low tensile stress SiN film 5 having a thickness of 600 Å and stress magnitude of 500 MPa is deposited on SiO₂ buffer film 4.

Afterwards, photoresist 6 is applied over the low tensile stress SiN film 5.

Step 3: UV radiation.

Referring to FIG. 3 of the drawings, the low tensile stress SiN film 5 on the NMOS region 2 is exposed through photoresist exposure. In addition, some SiN film 5 on the STI region 3 can also be exposed.

Referring to FIG. 4 of the drawings, UV radiation is applied to the exposed low tensile stress SiN film 5 in a direction illustrated by the arrows in FIG. 4. Since the PMOS region is covered by the photoresist, UV light cannot be radiated on the low tensile stress SiN film 5 on the PMOS region 1. Therefore, the PMOS region will not be affected by UV radiation.

Referring to FIG. 7 of the drawings, the hydrogen element of the low tensile stress SiN film 5 on the NMOS region decreases with the time of UV radiation, while the stress magnitude of the low tensile stress SiN 5 film increases.

Referring to FIG. 4 and FIG. 5, after UV radiation being applied for 10 minutes, the stress magnitude of the low tensile stress SiN film on the NMOS region 2 reaches 1800 MPa. After UV radiation is stopped, a high tensile stress nitride film 51 is formed and the low tensile stress SiN film 5 on PMOS region will not be affected.

Then, the photoresist is removed.

Step 4: Rapid Thermal Annealing (RTA) process.

Referring to FIG. 6, a rapid thermal annealing process is performed and the stress in the high tensile stress nitride film 51 is “memorized”, that is, the high tensile stress is induced in the channel region of the NMOS region 2.

Step 5: Removing the SiO₂ buffer film 4, the low tensile stress nitride film 5, and the high tensile stress nitride film 51 on the NMOS region 2.

### Third Embodiment

Step 1: providing a substrate.

Referring to FIG. 1 of the drawings, the substrate includes PMOS region 1, NMOS region 2, and an STI region 3 isolating the PMOS region 1 from the NMOS region 2. A PMOS gate electrode and an NMOS gate electrode are formed on the PMOS region 1 and the NMOS region 2 respectively. P-type source/drain regions are formed adjacent to the PMOS gate electrode and N-type source/drain regions are formed adjacent to the NMOS gate electrode.

Step 2: deposition.

Referring to FIG. 2 of the drawings, an SiO₂ buffer film 4 having a thickness of about 200 Å is deposited on the substrate via PECVD or SACVD, and the gate electrode, the source/drain regions of the PMOS region 1 and the NMOS region 2 as well as the STI region 3 are covered by the SiO₂ buffer film.

Then, a low tensile stress SiN film 5 having a thickness of 800 Å and stress magnitude of 200 MPa is deposited on SiO₂ buffer film 4.

Photoresist 6 is applied over the low tensile stress SiN film 5.

Step 3: UV radiation.

Referring to FIG. 3 of the drawings, the low tensile stress SiN film 5 on the NMOS region 2 is exposed through photoresist exposure. In addition, some SiN film 5 on the STI region 3 can also be exposed.

Referring to FIG. 4 of the drawings, UV radiation is applied to the exposed low tensile stress SiN film 5 in a direction illustrated by the arrows in FIG. 4. Since the PMOS region is covered by the photoresist, UV light cannot be radiated on the low tensile stress SiN film 5 on the PMOS region 1. Therefore, the PMOS region will not be affected by UV radiation.

Referring to FIG. 7 of the drawings, the hydrogen element of the low tensile stress SiN film on the NMOS region decreases with the time of UV radiation, while the stress magnitude of the low tensile stress SiN film increases.

Referring to FIG. 4 and FIG. 5, after UV radiation being applied for 10 minutes, the stress magnitude of the low tensile stress SiN film on NMOS region 2 reaches 1200 MPa. After UV radiation is stopped, a high tensile stress nitride film 51 is formed and the low tensile stress SiN film 5 on PMOS region will not be affected.

Then, the photoresist is removed.

Step 4: Rapid Thermal Annealing (RTA) process.

Referring to FIG. 6, a rapid thermal annealing process is performed and the stress in the high tensile stress nitride film 51 is “memorized”, that is, the high tensile stress is induced in the channel region of the NMOS region 2.

Step 5: Removing the SiO₂ buffer film 4, the low tensile stress nitride film 5, and the high tensile stress nitride film 51 on the NMOS region 2.

In summary, the method of forming semiconductor devices using SMT simplifies the conventional SMT process and increases the integrity of the tensile stress SiN film. Therefore, the process cost of SMT can be reduced and the performance of the PMOS transistor will not be affected.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. A method of forming semiconductor devices using SMT comprising:
Step 1: providing a substrate including NMOS region and PMOS region;
Step 2:depositing an SiO₂ buffer film and a low tensile stress SiN film on the substrate sequentially followed by applying photoresist over the low tensile stress SiN film;
Step 3: exposing the low tensile stress SiN film on the NMOS region through photoresist exposure and applying UV radiation to the exposed low tensile stress SiN film;
removing some hydrogen element in the low tensile stress SiN film on the NMOS region and removing photoresist over the PMOS region;
Step 4: performing a rapid thermal annealing process to induce tensile stress in the NMOS channel region;
Step 5: removing the SiN film and the SiO₂ buffer film.

2. The method according to claim 1, wherein, the silicon oxide buffer film is deposited by PECVD or SACVD.

3. The method according to claim 1, wherein, the SiO₂ buffer film has a thickness of about 50 Å˜200 Å.

4. The method according to claim 1, wherein, the stress of the low tensile stress SiN film has a magnitude in the range from about 200 MPa to 400 MPa.

5. The method according to claim 4, wherein, the low tensile stress SiN film has a thickness of about 200 Å˜800 Å.

6. The method according to claim 5, wherein, the stress of the low tensile stress SiN film has a magnitude in the range from about 1000 MPa to 1800 MPa after being exposed and applied UV radiation in step 3.

7. The method according to claim 6, the UV radiation is applied for about 1 minute to 10 minutes.
